(19) United States
(12) Patent Application Publication
(10) Pub. No.: US 2024/0179886 A1
(43) Pub. Date: May 30, 2024

(54) MEMORY-ELEMENT-INCLUDING SEMICONDUCTOR DEVICE

(71) Applicant: Unisantis Electronics Singapore Pte. Ltd., Singapore (SG)

(72) Inventors: Nozomu HARADA, Tokyo (JP); Masakazu KAKUMU, Tokyo (JP); Koji SAKUI, Tokyo (JP)

(21) Appl. No.: 18/517,572

(22) Filed: Nov. 22, 2023

(30) Foreign Application Priority Data
Nov. 28, 2022 (WO) PCT/JP2022/043781
May 26, 2023 (WO) PCT/JP2023/019722

(51) Int. Cl. H10B 12/00; G11C 11/405; G11C 11/4096

(52) U.S. Cl. CPC H10B 12/20; G11C 11/405; G11C 11/4096

(57) ABSTRACT

In a memory cell including a first gate insulating layer 5 and a first gate conductor layer 6 surrounding a pillar-shaped P layer 3a standing on a P layer substrate 1, a second gate insulating layer 9 in contact with a P layer 3b in contact with an upper surface of the P layer 3a, and N⁺ layers 11a and 11b at both ends of the P layer 3b and a MOS transistor including a pillar-shaped P layer 3aa standing on a P layer substrate 1a connecting to the same P layer substrate 1, a third gate insulating layer 9a in contact with the P layer 3aa, a third gate conductor layer 10a, and N⁺ layers 11aa and 11ba at both ends of a P layer 3ba, bottom portions of the P layer 3b and the P layer 3ba are located at substantially the same position.

### CROSS-REFERENCE TO RELATED APPLICATIONS

This application claims priority to PCT/JP2023/019722, filed May 26, 2023, which claims priority to PCT/JP2022/043781, filed Nov. 28, 2022. The entire contents of these applications are incorporated herein by reference.

### BACKGROUND OF THE INVENTION

### 1. Field of the Invention

The present invention relates to a memory-element-including semiconductor device.

### 2. Description of the Related Art

In recent years, in the development of large-scale integration (LSI) technologies, there have been demands for higher degree of integration, higher performance, lower power consumption, and higher functionality of memory-element-including semiconductor devices.

Typical planar MOS transistors have a channel that extends in a horizontal direction along an upper surface of a semiconductor substrate. In contrast, surrounding gate transistors (SGTs) have a channel that extends in a direction perpendicular to an upper surface of a semiconductor substrate (refer to, for example, Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). For this reason, SGTs enable an increase in the density of semiconductor devices compared with planar MOS transistors. Such SGTs can be used as select transistors to achieve an increase in the degree of integration of memories, such as a dynamic random access memory (DRAM) to which a capacitor is connected (refer to, for example, H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT)”, 2011 Proceeding of the European Solid-State Device Research Conference, (2011)); a phase change memory (PCM) to which a resistance-change element is connected (refer to, for example, H. S. Philip Wong, S. Raoux, S. Kim, Jiale Liang, J. R. Reifenberg, B. Rajendran, M. Asheghi and K. E. Goodson: “Phase Change Memory”, Proceeding of IEEE, Vol. 98, No. 12, December, pp. 2201-2227 (2010)); a resistive random access memory (RRAM) (refer to, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V”, IEDM (2007)); and a magneto-resistive random access memory (MRAM) in which the orientation of the magnetic spin is changed with a current to change the resistance (refer to, for example, W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transaction on Electron Devices, pp. 1-9 (2015)). There are also, for example, a capacitor-less DRAM memory cell constituted by a single MOS transistor (refer to M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron”, IEEE Electron Device Letter, Vol. 31, No. 5, pp. 405-407 (2010)); and a DRAM memory cell having two groove portions for storing carriers and two gate electrodes (refer to Md. Hasan Raza Ansari, Nupur Navlakha, Jae Yoon Lee, Seongjae Cho, “Double-Gate Junctionless 1T DRAM With Physical Barriers for Retention Improvement” IEEE Trans, on Electron Devices vol. 67, pp. 1471-1479 (2020)). However, capacitor-less DRAMs have a problem in that they are considerably affected by, in the floating bodies, coupling of gate electrodes due to word lines, and a sufficient voltage margin cannot be provided. This application relates to a memory-element-including semiconductor device that does not include resistance-change elements or capacitors and that can be constituted by MOS transistors alone.

### SUMMARY OF THE INVENTION

In a memory device, memory cells and MOS transistors of a peripheral logic circuit need to be produced at high density and low cost.

In order to address the above problem, a memory-element-including semiconductor device according to a first invention is a semiconductor device including:
a memory element; and
a MOS transistor,
wherein the memory element includes
a pillar-shaped first semiconductor layer that stands on a substrate in a direction perpendicular to the substrate,
a first impurity region connecting to a bottom portion of the first semiconductor layer,
a first gate insulating layer in contact with a side surface of the first semiconductor layer,
a first gate conductor layer in contact with a side surface of the first gate insulating layer,
a first insulating layer disposed between the first impurity region and the first gate conductor layer,
a second semiconductor layer continuous with an upper portion of the first semiconductor layer,
a second impurity region and a third impurity region in contact with both ends of the second semiconductor layer in a horizontal direction,
a second gate insulating layer in contact with the second semiconductor layer between the second impurity region and the third impurity region, and
a second gate conductor layer in contact with the second gate insulating layer,
the MOS transistor includes
a pillar-shaped third semiconductor layer that stands on the substrate in the direction perpendicular to the substrate,
a first material layer in contact with a side surface of the third semiconductor layer,
a fourth semiconductor layer continuous with an upper portion of the third semiconductor layer,
a fourth impurity region and a fifth impurity region in contact with both ends of the fourth semiconductor layer in the horizontal direction,
a third gate insulating layer in contact with the fourth semiconductor layer between the fourth impurity region and the fifth impurity region, and
a third gate conductor layer in contact with the third gate insulating layer, and
a top portion of the first semiconductor layer and a top portion of the third semiconductor layer are located at substantially the same position in the perpendicular direction.

According to a second invention, in the first invention, the first material layer is an insulating layer.

According to a third invention, in the first invention, the first material layer is formed of, from a bottom, a second insulating layer, a third insulating layer in contact with the side surface of the third semiconductor layer, a first conductor layer in contact with a side surface of the third insulating layer, and a fourth insulating layer covering the first conductor layer and being in contact with the third insulating layer.

According to a fourth invention, in the third invention, a fixed voltage or a voltage that changes with time is applied to the first conductor layer.

According to a fifth invention, in the third invention, the memory-element-including semiconductor device includes a sixth impurity region connecting to a bottom portion of the third semiconductor layer.

According to a sixth invention, in the first invention, an upper surface of the second semiconductor layer and an upper surface of the fourth semiconductor layer are located at substantially the same position in the perpendicular direction.

According to a seventh invention, in the first invention, a bottom portion of the first semiconductor layer and a bottom portion of the third semiconductor layer are located at substantially the same position in the perpendicular direction.

According to an eighth invention, in the first invention, a bottom portion of the first semiconductor layer and a bottom portion of the third semiconductor layer are located at different positions in the perpendicular direction.

According to a ninth invention, in the first invention, an entirety or part of the first insulating layer has a material layer that is an extension of the first gate insulating layer.

According to a tenth invention, in the first invention, at a boundary portion between the first semiconductor layer and the second semiconductor layer, in a direction from the second impurity region toward the third impurity region, a length of a top portion of the first semiconductor layer is greater than a length of a bottom portion of the second semiconductor layer,
the second impurity region is formed of, from a side in contact with the second semiconductor layer to the outside, a first low-concentration impurity region having a low impurity concentration and a first high-concentration impurity region having a high impurity concentration, and
the third impurity region is formed of, from the side in contact with the second semiconductor layer to the outside, a second low-concentration impurity region having a low impurity concentration and a second high-concentration impurity region having a high impurity concentration.

According to an eleventh invention, in the tenth invention, at a boundary portion between the third semiconductor layer and the fourth semiconductor layer, in a direction from the fourth impurity region toward the fifth impurity region, a length of a top portion of the third semiconductor layer is greater than a length of a bottom portion of the fourth semiconductor layer,
the fourth impurity region is formed of, from a side in contact with the fourth semiconductor layer to the outside, a third low-concentration impurity region having a low impurity concentration and a third high-concentration impurity region having a high impurity concentration, and
the fifth impurity region is formed of, from the side in contact with the fourth semiconductor layer to the outside, a fourth low-concentration impurity region having a low impurity concentration and a fourth high-concentration impurity region having a high impurity concentration.

According to a twelfth invention, in the first invention, a transistor composed of the second semiconductor layer, the second gate insulating layer, the second gate conductor layer, the second impurity region, and the third impurity region of the memory element is a planar MOS transistor, and a transistor composed of the fourth semiconductor layer, the third gate insulating layer, the third gate conductor layer, the fourth impurity region, and the fifth impurity region is a planar MOS transistor.

According to a thirteenth invention, in the first invention, a transistor composed of the second semiconductor layer, the second gate insulating layer, the second gate conductor layer, the second impurity region, and the third impurity region of the memory element is a planar MOS transistor, and a transistor composed of the fourth semiconductor layer, the third gate insulating layer, the third gate conductor layer, the fourth impurity region, and the fifth impurity region is a fin MOS transistor.

According to a fourteenth invention, in the first invention, a transistor composed of the second semiconductor layer, the second gate insulating layer, the second gate conductor layer, the second impurity region, and the third impurity region of the memory element is a MOS transistor in which the second semiconductor layer has a U-shaped section.

According to a fifteenth invention, in the first invention, the first impurity region connects to a bottom portion of a first semiconductor layer of another memory cell adjacent to the first semiconductor layer.

According to a sixteenth invention, in the first invention, the first impurity region is isolated from an impurity layer in a bottom portion of a first semiconductor layer of another memory cell adjacent to the first semiconductor layer.

According to a seventeenth invention, in the first invention, the first gate conductor layer is divided into two parts in a horizontal section.

According to an eighteenth invention, in the first invention, the first gate conductor layer is divided into two parts in the perpendicular direction.

According to a nineteenth invention, in the first invention, the first insulating layer is a thermally oxidized layer.

According to a twentieth invention, in the first invention, the first impurity region, the second impurity region, the third impurity region, the first gate conductor layer, and the second gate conductor layer are configured to perform
a memory write operation of controlling voltages applied to the first impurity region, the second impurity region, the third impurity region, the first gate conductor layer, and the second gate conductor layer to generate, in the second semiconductor layer, a group of electrons and a group of positive holes by an impact ionization phenomenon using a current flowing between the second impurity region and the third impurity region or by a gate-induced drain-leakage current and cause, of the generated group of electrons and the generated group of positive holes, a portion or entirety of the group of electrons or the group of positive holes serving as majority carriers to remain mainly in the first semiconductor layer surrounded by the first gate insulating layer, and
a memory erase operation of discharging the group of electrons or the group of positive holes serving as the remaining majority carriers mainly from one or both of the second impurity region and the third impurity region.

### BRIEF DESCRIPTION OF THE DRAWINGS

FIG. 1 is a sectional structural view of a memory cell included in a semiconductor device according to an embodiment.

FIGS. 2A, 2B, and 2C are explanatory views of a write operation in a memory cell included in a semiconductor device according to an embodiment.

FIGS. 3A, 3B, and 3C are explanatory views of an erase operation in a memory cell included in a semiconductor device according to an embodiment.

FIGS. 4AA and 4AB are explanatory views of structures of a memory cell and a MOS transistor of a logic circuit that are formed on the same substrate, according to the embodiment.

FIGS. 4BA and 4BB are explanatory views of planar structures of the memory cell and the MOS transistor of the logic circuit that are formed on the same substrate, according to the embodiment.

FIGS. 5A and 5B are explanatory views of sectional structures of a memory cell and a MOS transistor of a logic circuit that are formed on the same substrate, according to the embodiment.

FIGS. 6A and 6B are explanatory views of sectional structures of a memory cell and a MOS transistor of a logic circuit that are formed on the same substrate, according to the embodiment.

FIGS. 7A and 7B are explanatory views of sectional structures of a memory cell and a MOS transistor of a logic circuit that are formed on the same substrate, according to the embodiment.

FIGS. 8AA and 8AB are explanatory views of a production method in which a memory cell and a MOS transistor of a logic circuit according to the embodiment are formed on the same substrate.

FIGS. 8BA and 8BB are explanatory views of a production method in which a memory cell and a MOS transistor of a logic circuit according to the embodiment are formed on the same substrate.

FIGS. 8CA and 8CB are explanatory views of a production method in which a memory cell and a MOS transistor of a logic circuit according to the embodiment are formed on the same substrate.

FIGS. 8DA and 8DB are explanatory views of a production method in which a memory cell and a MOS transistor of a logic circuit according to the embodiment are formed on the same substrate.

FIGS. 8EA and 8EB are explanatory views of a production method in which a memory cell and a MOS transistor of a logic circuit according to the embodiment are formed on the same substrate.

FIGS. 8FA and 8FB are explanatory views of a production method in which a memory cell and a MOS transistor of a logic circuit according to the embodiment are formed on the same substrate.

FIGS. 8GA and 8GB are explanatory views of a production method in which a memory cell and a MOS transistor of a logic circuit according to the embodiment are formed on the same substrate.

FIGS. 8HA and 8HB are explanatory views of a production method in which a memory cell and a MOS transistor of a logic circuit according to the embodiment are formed on the same substrate.

FIGS. 8IA and 8IB are explanatory views of a production method in which a memory cell and a MOS transistor of a logic circuit according to the embodiment are formed on the same substrate.

FIGS. 8JA and 8JB are explanatory views of a production method in which a memory cell and a MOS transistor of a logic circuit according to the embodiment are formed on the same substrate.

FIGS. 8KA and 8KB are explanatory views of a production method in which a memory cell and a MOS transistor of a logic circuit according to the embodiment are formed on the same substrate.

FIGS. 8LA and 8LB are explanatory views of a production method in which a memory cell and a MOS transistor of a logic circuit according to the embodiment are formed on the same substrate.

FIGS. 9AA and 9AB are explanatory views of a production method in which a memory cell and a MOS transistor of a logic circuit according to the embodiment are formed on the same substrate.

FIGS. 9BA and 9BB are explanatory views of a production method in which a memory cell and a MOS transistor of a logic circuit according to the embodiment are formed on the same substrate.

FIGS. 9CA and 9CB are explanatory views of a production method in which a memory cell and a MOS transistor of a logic circuit according to the embodiment are formed on the same substrate.

### DESCRIPTION OF THE PREFERRED EMBODIMENTS

A memory-element-including semiconductor device according to an embodiment of the present invention and a method for producing the memory-element-including semiconductor device will be described below with reference to the drawings.

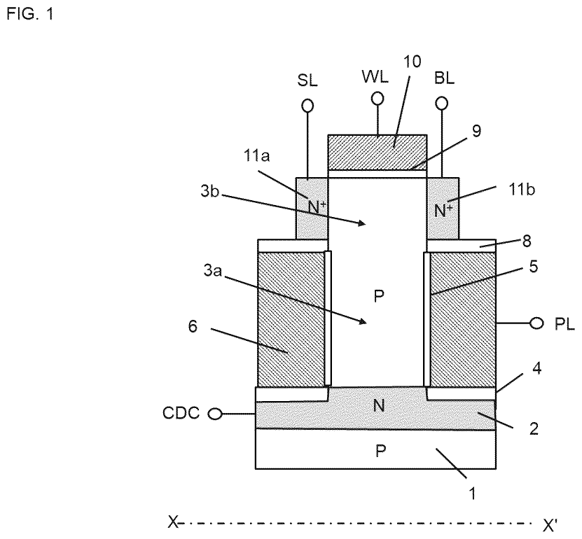

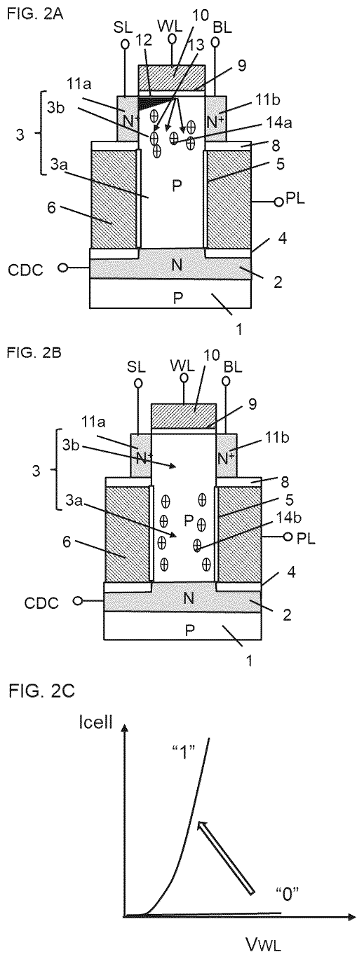

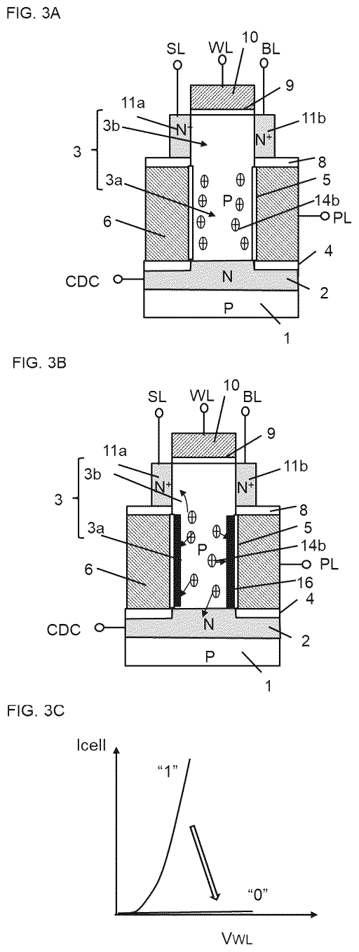

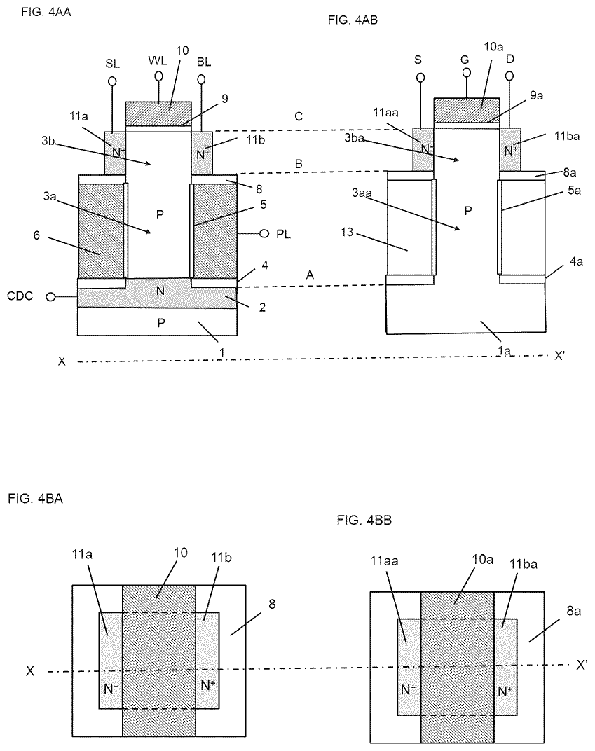

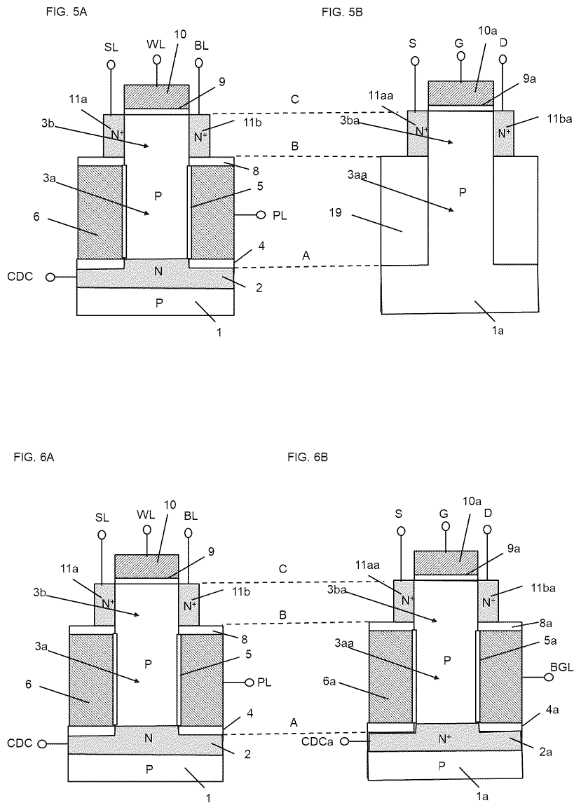

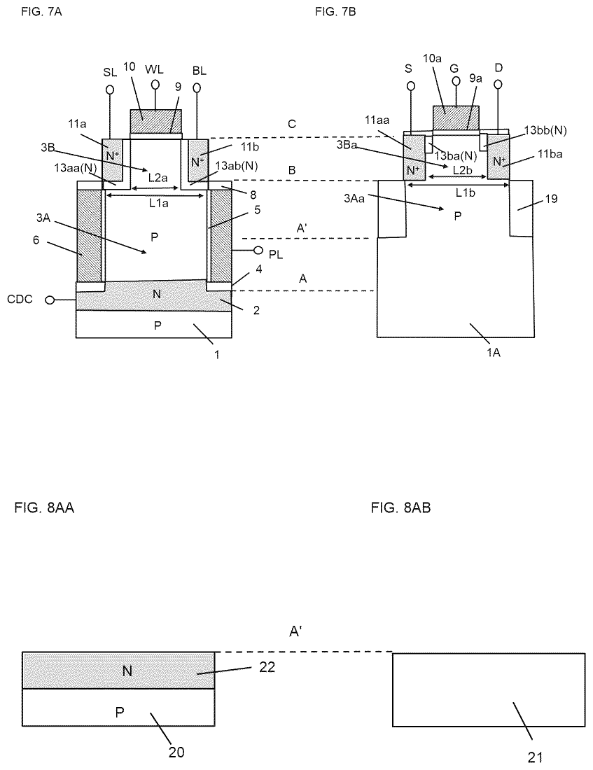

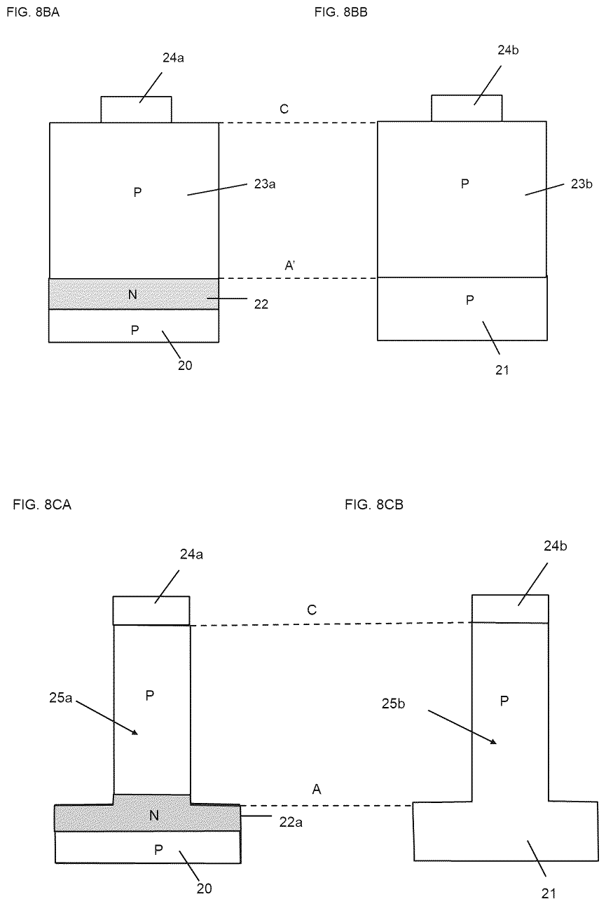

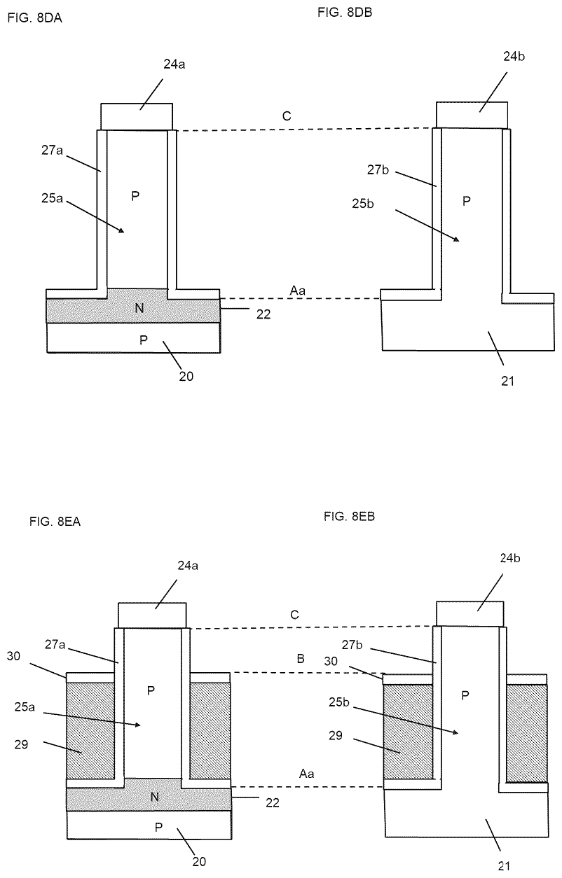

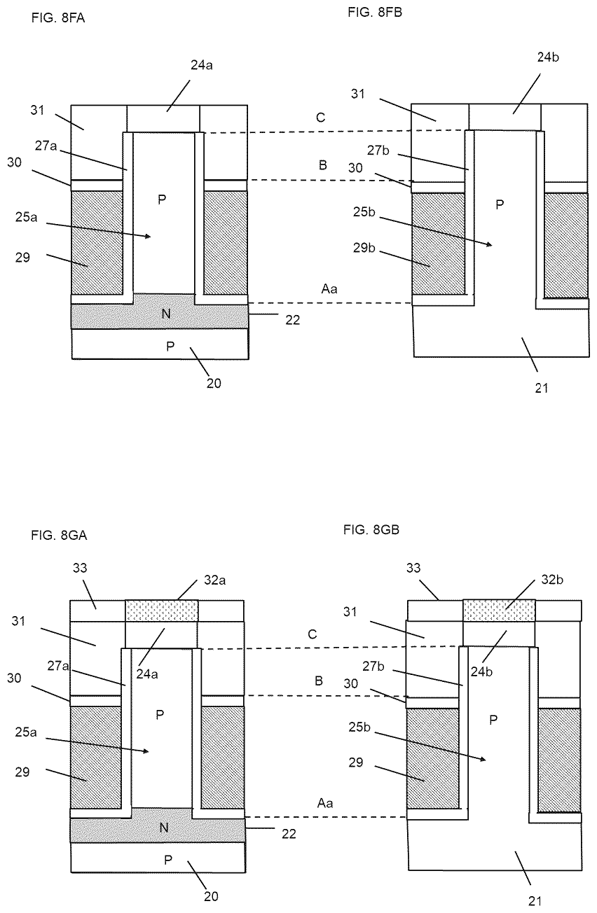

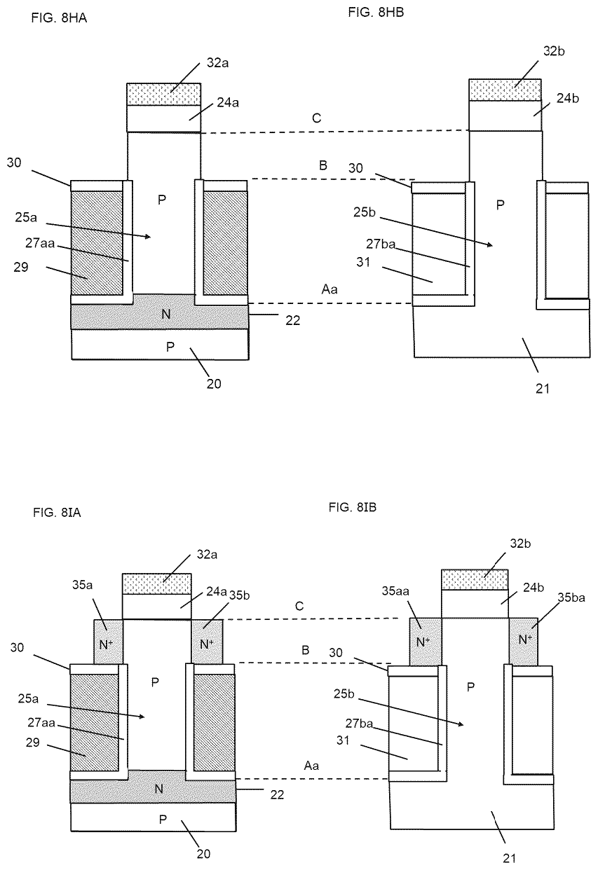

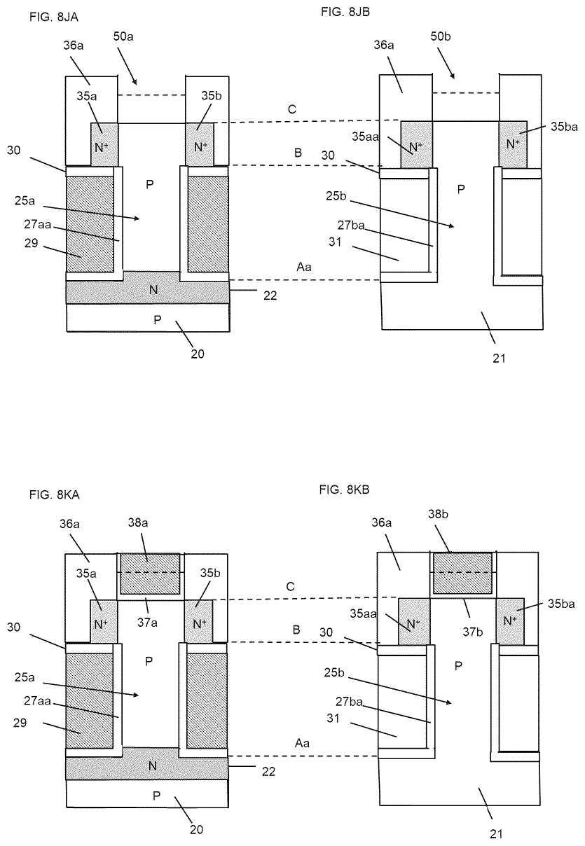

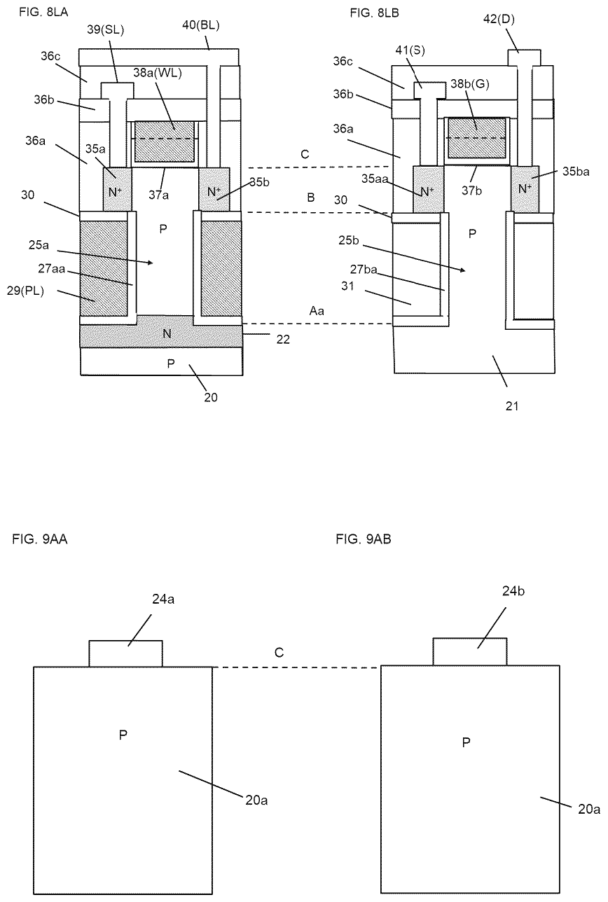

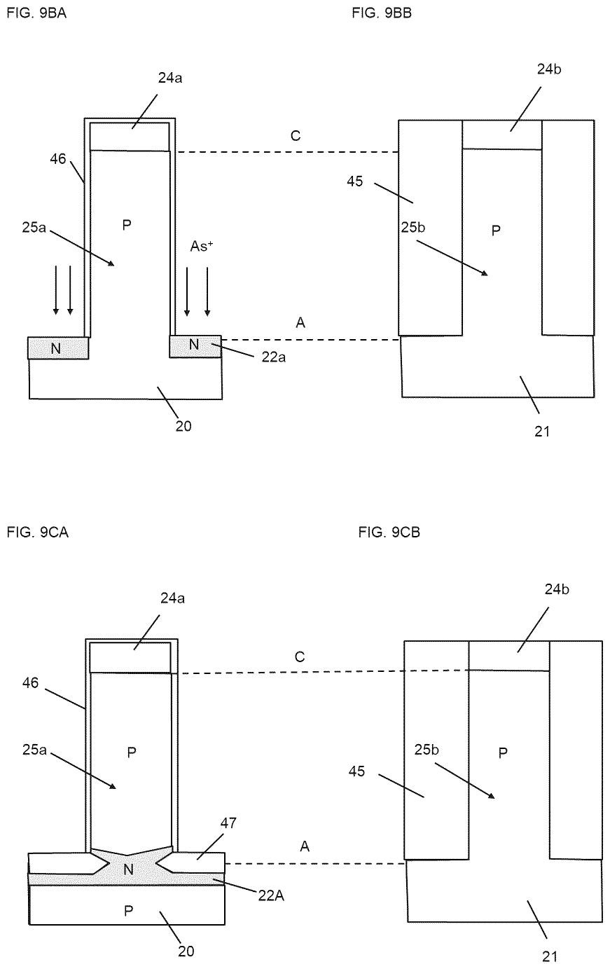

The structure of a memory cell according to this embodiment will be described with reference to FIG. 1. A write mechanism of the memory cell according to the embodiment will be described with reference to FIGS. 2A, 2B, and 2C. A data erase mechanism of the memory cell according to the embodiment will be described with reference to FIGS. 3A, 3B, and 3C. The structures of a memory cell and a MOS transistor (MOS field-effect transistor, hereinafter referred to as a MOS transistor) of a logic circuit that are formed on the same substrate, according to the embodiment will be described with reference to FIGS. 4AA and 4AB, FIGS. 4BA and 4BB, FIGS. 5A and 5B, FIGS. 6A and 6B, and FIGS. 7A and 7B. A method for producing a memory cell and a MOS transistor of a logic circuit according to the embodiment, the memory cell and the MOS transistor being illustrated in FIGS. 4AA and 4AB and FIGS. 4BA and 4BB and formed on the same substrate, will be described with reference to FIGS. 8AA and 8AB to FIGS. 8LA and 8LB. A method for producing another memory cell and another MOS transistor of a logic circuit according to the embodiment will be described with reference to FIGS. 9AA and 9AB to FIGS. 9CA and 9CB.

FIG. 1 illustrates a vertical sectional structure of a memory cell included in a semiconductor device according to an embodiment of the present invention. On a P layer substrate 1 (which is an example of “substrate” in the claims), an N layer 2 (which is an example of “first impurity region” in the claims) containing a donor impurity is disposed (hereinafter, a semiconductor region containing a donor impurity is referred to as an “N layer”). A pillar-shaped P layer 3a (which is an example of “first semiconductor layer” in the claims) containing an acceptor impurity is disposed as an upper layer of the N layer 2. A P layer 3b (which is an example of “second semiconductor layer” in the claims) is disposed on the P layer 3a. A first gate insulating layer 5 (which is an example of “first gate insulating layer” in the claims) is disposed in contact with a pillar-shaped side surface of the P layer 3a. A first gate conductor layer 6 (which is an example of “first gate conductor layer” in the claims) is disposed in contact with an outer side surface of the first gate insulating layer 5. A first insulating layer 4 (which is an example of “first insulating layer” in the claims) is disposed between the N layer 2 and the first gate conductor layer 6. A second insulating layer 8 is disposed on the first gate insulating layer 5 and the first gate conductor layer 6. An N⁺ layer 11a (which is an example of “second impurity region” in the claims) and an N⁺ layer 11b (which is an example of “third impurity region” in the claims) that contain a donor impurity at a high concentration are disposed on both sides of the P layer 3b in a direction of line X-X′. The plan view is shown in FIG. 4BA described later. A second gate insulating layer 9 (which is an example of “second gate insulating layer” in the claims) is in contact with an upper portion of the P layer 3b between the N⁺ layer 11a and the N⁺ layer 11b. A second gate conductor layer 10 (which is an example of “second gate conductor layer” in the claims) is disposed in contact with an upper portion of the second gate insulating layer 9.

The N⁺ layer 11a connects to a source line SL, the N⁺ layer 11b connects to a bit line BL, the second gate conductor layer 10 connects to a word line WL, the first gate conductor layer 6 connects to a plate line PL, and the N layer 2 connects to a control line CDC. The memory is operated by controlling the electric potentials of the source line SL, the bit line BL, the plate line PL, and the word line WL. In an actual memory device, a large number of the above-described memory cells are two-dimensionally arranged on the P layer substrate 1.

A write operation in the memory cell according to an embodiment of the present invention will be described with reference to FIGS. 2A, 2B, and 2C. As illustrated in FIG. 2A, a MOS transistor in this memory cell operates using, as elements, the N⁺ layer 11a serving as the source, the N⁺ layer 11b serving as the drain, the second gate insulating layer 9 serving as the gate insulating layer, the second gate conductor layer 10 serving as the gate, and the P layer 3b serving as the channel. For example, 0 V is applied to the P layer substrate 1, 0 V is input to the N⁺ layer 11a to which the source line SL is connected, 3 V is input to the N⁺ layer 11b to which the bit line BL is connected, 0 V is input to the first gate conductor layer 6 to which the plate line PL is connected, and 1.5 V is input to the second gate conductor layer 10 to which the word line WL is connected. In the P layer 3b immediately below the second gate insulating layer 9 underlying the second gate conductor layer 10, an inversion layer 12 is partly formed and a pinch-off point 13 is present. In this case, the MOS transistor including the second gate conductor layer 10 operates in the saturation region.

As a result, in the MOS transistor including the second gate conductor layer 10, the electric field becomes maximum between the pinch-off point 13 and the N⁺ layer 11b and, in this region, the impact ionization phenomenon occurs. As a result of this impact ionization phenomenon, electrons accelerated from the N⁺ layer 11a to which the source line SL is connected toward the N⁺ layer 11b to which the bit line BL is connected collide with the Si lattice, and electron-positive hole pairs are generated by the kinetic energy. The generated positive holes 14a diffuse toward regions having lower positive hole concentrations in accordance with their concentration gradient. Some of the generated electrons flow to the second gate conductor layer 10, but most of the generated electrons flow to the N⁺ layer 11b connected to the bit line BL. Note that, instead of causing the impact ionization phenomenon, a gate-induced drain-leakage (GIDL) current may be caused to flow to generate a group of positive holes 14a (refer to, for example, E. Yoshida, T, Tanaka, “A Capacitorless 1T-DARM Technology Using Gate-Induced Drain-Leakage (GIDL) Current for Low-Power and High-Speed Embedded Memory”, IEEE Trans, on Electron Devices vol. 53, pp. 692-697 (2006)).

FIG. 2B illustrates the group of positive holes 14b stored in the P layer 3a, immediately after the writing, when the word line WL, the bit line BL, the plate line PL, and the source line SL are at 0 V. Initially, the concentration of the generated positive holes is high in the region of the P layer 3b, and the positive holes move toward the P layer 3a by diffusion in accordance with their concentration gradient. The group of positive holes 14b is stored at a higher concentration in regions of the P layer 3a, the regions being close to the first gate insulating layer 5. As a result, the P layer 3a has a positive hole concentration higher than the positive hole concentration of the P layer 3b. Since the P layer 3a and the P layer 3b are electrically connected together, the P layer 3a that substantially serves as a substrate of the MOS transistor including the second gate conductor layer 10 is charged to a positive bias. The threshold voltage of the MOS transistor including the second gate conductor layer 10 is lowered by the positive substrate-bias effect due to the group of positive holes 14b stored in the P layer 3a. Thus, as illustrated in FIG. 2C, the MOS transistor including the second gate conductor layer 10 to which the word line WL is connected has a lowered threshold voltage. This write state is assigned to logical storage data “1”. Note that the above voltage conditions applied to the bit line BL, the source line SL, the word line WL, and the plate line PL are an example for performing the write operation, and alternatively, other voltage conditions under which the write operation can be performed may be employed.

Next, an erase operation mechanism will be described with reference to FIGS. 3A, 3B, and 3C. FIG. 3A illustrates a state, prior to an erase operation, immediately after the group of positive holes 14b generated by impact ionization and stored are stored mainly in the P layer 3a. At the time of the erase operation, a negative voltage VERA is applied to the source line SL. The voltage of the plate line PL is set to, for example, 2 V. Here, VERA is, for example, −0.5 V. As a result, regardless of the initial electric potential value of the P layer 3a, the PN junction between the P layer 3b and the N⁺ layer 11a to which the source line SL is connected and which serves as the source is forward biased. As a result, as illustrated in FIG. 3B, the group of positive holes 14b generated by impact ionization in the previous cycle and stored mainly in the P layer 3a moves to the N⁺ layer 11a connected to the source line. As a result of application of a voltage of 2 V to the plate line PL, an inversion layer 16 is formed at the interface between the first gate insulating layer 5 and the P layer 3a and in contact with the N layer 2. Thus, the positive holes 14b stored in the P layer 3a flow from the P layer 3a to the N layer 2 and the inversion layer 16 and recombine with electrons. As a result, the positive hole concentration of the P layer 3a decreases with time, and the threshold voltage of the MOS transistor becomes higher than that at the time of writing of “1”, resulting in a return to the initial state. Thus, as illustrated in FIG. 3C, the MOS transistor including the second gate conductor layer 10 to which the word line WL is connected returns to the initial threshold. This erase state of the memory is assigned to logical storage data “0”.

At the time of erasing of data, when, for example, 2 V is applied to the plate line PL, the N⁺ layer 11a, the N⁺ layer 11b, and the N layer 2 can be electrically connected together by the inversion layer 16 to shorten the data erase time. In this case, the thickness of each of the first insulating layer 4 and the second insulating layer 8 is preferably substantially the same as the thickness of the first gate insulating layer 5. The above voltage conditions applied to the bit line BL, the source line SL, the word line WL, and the plate line PL are an example for performing the erase operation, and alternatively, other voltage conditions under which the erase operation can be performed may be employed.

The structures of a memory cell and a MOS transistor of a logic circuit that are formed on the same substrate, according to the embodiment will be described with reference to FIGS. 4AA and 4AB and FIGS. 4BA and 4BB. FIG. 4AA illustrates a sectional structure of a memory cell. FIG. 4AB illustrates a sectional structure of a MOS transistor of a logic circuit formed on the same substrate as that of the memory cell. FIG. 4BA is a plan view of the memory cell. FIG. 4BB is a plan view the MOS transistor of the logic circuit formed on the same substrate as that of the memory cell. In FIGS. 4AA and 4AB and FIGS. 4BA and 4BB, components that are the same as those illustrated in FIG. 1 are assigned the same reference numerals.

The memory cell structure illustrated in FIG. 4AA is the same as that in FIG. 1. In the MOS transistor of the logic circuit illustrated in FIG. 4AB, a pillar-shaped P layer 3aa (which is an example of “third semiconductor layer” in the claims) standing in a perpendicular direction is disposed on a Player substrate 1a connecting to the P layer substrate 1 (which is an example of “substrate” in the claims). A first material layer (which is an example of “first material layer” in the claims) formed of an insulating layer 5a in contact with a side surface of the pillar-shaped P layer 3aa and insulating layers 4a, 13, and 8a that are stacked, from the bottom, on an outer peripheral portion of the insulating layer 5a is disposed. A P layer 3ba (which is an example of “fourth semiconductor layer” in the claims) is disposed on the P layer 3aa. An N⁺ layer 11aa (which is an example of “fourth impurity region” in the claims) and an N⁺ layer 11ba (which is an example of “fifth impurity region” in the claims) that contain a donor impurity at a high concentration are disposed in contact with both ends of the P layer 3ba in the horizontal direction. A third gate insulating layer 9a (which is an example of “third gate insulating layer” in the claims) is disposed in contact with an upper portion of the P layer 3ba between the N⁺ layer 11aa and the N⁺ layer 11ba. A third gate conductor layer 10a (which is an example of “third gate conductor layer” in the claims) is disposed in contact with the top of the third gate insulating layer 9a.

The third gate conductor layer 10a connects to a gate line G, the N⁺ layer 11aa connects to a source line S, and the N⁺ layer 11ba connects to a drain line D. The insulating layers 4a, 5a, 8a, and 13 may be layers made of different materials or layers made of the same material, or the insulating layer 13 may be formed as a conductor layer. Thus, the material layer formed of the insulating layers 4a, 5a, 8a, and 13 can be in a form including a conductor material or a form that does not include a conductor material.

An upper surface of the P layer 3a which is the first semiconductor layer and an upper surface of the P layer 3aa which is the third semiconductor layer (line B in the figures) are located at substantially the same position. In FIGS. 4AA and 4AB, a bottom portion of the P layer 3a which is the first semiconductor layer and a bottom portion of the P layer 3aa which is the third semiconductor layer (line A in the figures) are illustrated so as to be located at substantially the same position; alternatively, the bottom portions may be located at different positions. Similarly, in FIGS. 4AA and 4AB, an upper surface of the P layer 3b which is the second semiconductor layer and an upper surface of the P layer 3ba which is the fourth semiconductor layer (line C in the figures) are illustrated so as to be located at substantially the same position; alternatively, the upper surfaces may be located at different positions.

FIG. 4BA is a plan view of a portion corresponding to the sectional view of the memory cell in FIG. 4AA. FIG. 4BB is a plan view of a portion corresponding to the sectional view of the MOS transistor of the logic circuit in FIG. 4AB. FIGS. 4AA and 4AB are sectional views taken along line X-X′ in FIGS. 4BA and 4BB. In FIGS. 4BA and 4BB, the arrangement and shape of the N⁺ layers 11a and 11b of the memory cell and those of the N⁺ layers 11aa and 11ba of the MOS transistor of the logic circuit are the same, and the arrangement and shape of the second gate conductor layer 10 in the memory cell and those of the third gate conductor layer 10a in the MOS transistor of the logic circuit are the same. In contrast, in plan view, the dimensions of the P layers 3a and 3b and the N⁺ layers 11a and 11b may be actually made different in accordance with the design requirements.

Both the MOS transistors in FIGS. 4AA and 4AB are formed of the same planar MOS transistors or fin MOS transistors. In contrast, one of the MOS transistors in FIGS. 4AA and 4AB may be formed of a planar MOS transistor and the other may be formed of a fin MOS transistor. A section of the channel of one or both of the MOS transistors in FIGS. 4AA and 4AB may have a U-shape (refer to Takashi Ohasawa and Takeshi Hamamoto, “Floating Body Cell—a Novel Body Capacitorless DRAM Cell”, Pan Stanford Publishing (2011)). In this case, the N⁺ layers corresponding to the N⁺ layers 11a, 11b, 11aa, and 11ba are formed to connect to both ends of the U-shaped channel.

In a CMOS circuit in the region of the logic circuit, an N-channel MOS transistor and a P-channel MOS transistor are formed on the same substrate connecting to the Player substrate 1. In the P-channel MOS transistor, the N⁺ layers 11aa and 11ba are formed as P⁺ layers, and, for example, the structural dimensions, impurity concentrations, and the formation of an N-layer well layer are changed from those of the N-channel MOS transistor in accordance with the design requirements, but the basic structures are the same. Moreover, in the region of the logic circuit, a shallow trench isolation (STI) region or a deep trench isolation (DTI) region for isolating an N-channel MOS transistor and an N-channel MOS transistor from each other is present.

In the logic circuit region, a plurality of N-channel MOS transistors or P-channel MOS transistors or a plurality of N-channel and P-channel MOS transistors may be formed on a single Player 3aa. This also applies to the other embodiments.

In a direction in which the N⁺ layers 11a and 11b connect together, when viewed from above, a first N layer having a low concentration may be disposed between the second gate conductor layer 10 and the N⁺ layer 11a to be in contact with the N⁺ layer 11a, and a second N layer having a low impurity concentration may be disposed between the second gate conductor layer 10 and the N⁺ layer 11b to be in contact with the N⁺ layer 11b. Similarly, in a direction in which the N⁺ layers 11aa and 11ba connect together, when viewed from above, a third N layer having a low impurity concentration may be disposed between the third gate conductor layer 10a and the N⁺ layer 11aa to be in contact with the N⁺ layer 11aa, and a fourth N layer having a low concentration may be disposed between the third gate conductor layer 10a and the N⁺ layer 11ba to be in contact with the N⁺ layer 11ba. Alternatively, the first to fourth N layers may be low-impurity-concentration regions that are not doped with a donor impurity. This also applies to the other embodiments.

Another example of the structures of a memory cell and a MOS transistor of a logic circuit that are formed on the same substrate, according to the embodiment will be described with reference to FIGS. 5A and 5B. FIG. 5A illustrates a sectional structure of a memory cell. FIG. 5B illustrates a sectional structure of a MOS transistor of a logic circuit formed on the same substrate as that of the memory cell. In FIGS. 5A and 5B, components that are the same as those illustrated in FIGS. 4AA and 4AB are assigned the same reference numerals.

The sectional structure of the memory cell illustrated in FIG. 5A is the same as that illustrated in FIG. 4AA. In the MOS transistor of the logic circuit illustrated in FIG. 5B, the insulating layers 4a, 5a, 8a, and 13 in FIG. 4AB are formed of a single insulating layer 19. In the memory cell, the insulating layers 4 and 8 need to be provided on and under the first gate conductor layer 6 which is a conductor layer. In contrast, in the MOS transistor of the logic circuit, since the portion corresponding to the first gate conductor layer 6 is an insulating layer, the portion may be formed of the single insulating layer 19 surrounding the P layer 3aa.

Note that, in the formation of the insulating layer 19, at least two or more of the insulating layers 4a, 5a, 8a, and 13 in FIG. 4AB may be formed at the same time. For example, the insulating layer 5a is left, and the insulating layers 4a, 13, and 8a may be formed at the same time. Alternatively, the insulating layers 4a and 5a may be formed at the same time. In this case, the insulating layers 4, 4a, 5, and 5a are formed at the same time. Alternatively, the insulating layers 13 and 8a may be formed at the same time.

Still another example of the structures of a memory cell and a MOS transistor of a logic circuit that are formed on the same substrate, according to the embodiment will be described with reference to FIGS. 6A and 6B. FIG. 6A illustrates a sectional structure of a memory cell. FIG. 6B illustrates a sectional structure of a MOS transistor of a logic circuit formed on the same substrate as that of the memory cell. In FIGS. 6A and 6B, components that are the same as those illustrated in FIGS. 4AA and 4AB or FIGS. 5A and 5B are assigned the same reference numerals.

The sectional structure of the memory cell illustrated in FIG. 6A is the same as that illustrated in FIG. 4AA. The MOS transistor of the logic circuit illustrated in FIG. 6B has the same basic structure as that in FIG. 6A. However, in FIG. 6A, the first gate conductor layer 6 connects to the plate line PL, and the N layer 2 is connected to the control line CDC. On the other hand, in FIG. 6B, a back gate conductor layer 6a connects to a back gate line BGL, and in FIG. 6B, an N⁺ layer 2a is connected to a control line CDCa. The voltage applied to the back gate line BGL is controlled to thereby control the voltage of the P layer 3aa. Thus, the threshold voltage of the MOS transistor composed of the P layer 3ba located on the P layer 3aa, the third gate insulating layer 9a, the third gate conductor layer 10a, and the N⁺ layers 11aa and 11ba is changed. In this manner, threshold voltages of a plurality of MOS transistors in the logic circuit can be set to values as desired by changing the voltage applied to the back gate line BGL. Note that, in FIG. 6B, the N⁺ layer 2a may not be provided. In this case, the voltage applied to the back gate line BGL is preferably driven under the condition under which the entire P layer 3aa is depleted. For this purpose, the acceptor impurity concentration of the P layer 3aa may be lower than the acceptor impurity concentration of the P layer 3ba.

In an actual logic circuit, MOS transistors having a plurality of threshold voltages are formed. This change in the threshold voltage is achieved by, for example, a method of using, as the third gate conductor layer 10a, a metal layer having a different work function or a method of changing the impurity concentration of the P layer 3ba. In contrast, according to the embodiment illustrated in FIGS. 6A and 6B, the threshold voltage can be set by merely changing the voltage applied to the back gate line BGL. In addition, the memory cell and the MOS transistor of the logic circuit have the same basic structure. This simplifies the production method and leads to a reduction in the cost of the memory device. Moreover, by changing the voltage applied to the back gate conductor layer 6a depending on the operation period, for example, the circuit power consumption can be reduced.

Still another example of the structures of a memory cell and a MOS transistor of a logic circuit that are formed on the same substrate, according to the embodiment will be described with reference to FIGS. 7A and 7B. FIG. 7A illustrates a sectional structure of a memory cell. FIG. 7B illustrates a sectional structure of a MOS transistor of a logic circuit formed on the same substrate as that of the memory cell. In FIGS. 7A and 7B, components that are the same as those illustrated in FIGS. 5A and 5B are assigned the same reference numerals.

In FIG. 5A, at a boundary surface between the P layer 3a and the P layer 3b, the lengths of the P layer 3a and the P layer 3b in the horizontal direction between the N⁺ layers 11a and 11b are the same. On the other hand, in the example illustrated in FIG. 7A, a length L1a of a P layer 3A corresponding to the P layer 3a in the horizontal direction is longer than a length L2a of a P layer 3B corresponding to the P layer 3b. In plan view, N⁺ layers 11a and 11b are disposed on an upper portion of the P layer 3A. N layers 13aa an 13ab containing a donor impurity are disposed between the P layers 3A and 3B and the N⁺ layers 11a and 11b. The N layers 13aa and 13ab are lightly doped drain (LDD) regions. The N layer 13aa is disposed so as to extend between the Players 3A and 3B and the N⁺ layer 11a. Similarly, the N layer 13ab is disposed so as to extend between the Players 3A and 3B and the N⁺ layer 11b. Note that, when viewed from above, the region of the N layers 13aa and 13ab may include at least regions that have been in contact with both ends of the second gate conductor layer 10 and that are not doped with a donor impurity.

In FIG. 5B, the lengths of the P layer 3aa and the P layer 3ba in the horizontal direction are the same. On the other hand, in the example illustrated in FIG. 7B, a length L1b of a P layer 3Aa corresponding to the P layer 3aa in the horizontal direction is longer than a length L2b of a P layer 3Ba corresponding to the P layer 3ba. In plan view, the N⁺ layers 11aa and 11ba are disposed on an upper portion of the P layer 3Aa. N layers 13ba an 13bb containing a donor impurity and serving as LDD are disposed between the P layer 3Ba and the N⁺ layer 11aa and between the P layer 3Ba and the N⁺ layer 11ba. In the perpendicular direction, a bottom portion of the P layer 3Aa (line A′ in the figure) is positioned higher than an upper surface of the N layer 2 (line A in the figure) at the periphery of a bottom portion of the P layer 3A of the memory cell. Note that, when viewed from above, the region of the N layers 13ba and 13bb may include at least regions that have been in contact with both ends of the third gate conductor layer 10a and that are not doped with a donor impurity. The N layers 13aa and 13ab illustrated in FIG. 7A may not surround the entire side surfaces of the N⁺ layers 11a and 11b, as illustrated in FIG. 7B.

The position of the bottom portion of the P layer 3Aa (line A′ in the figure) is determined in accordance with the design requirements of the MOS transistor of the logic circuit. Therefore, the bottom portion of the P layer 3Aa may be positioned at the same height or lower than the upper surface of the N layer 2 (line A in the figure) at the periphery of a bottom portion of the P layer 3A of the memory cell. Furthermore, in order to simplify the process, the N layers 13ba and 13bb may be formed so as to extend between the N⁺ layers 11aa and 11ba and the P layer 3Aa as in the N layers 13aa and 13ab in FIG. 7A. In the formation of the N⁺ layers 11a and 11b in FIG. 7A, the N⁺ layers 11a and 11b may be formed by forming, on the P layer 3A, a P layer having the same shape as that of the P layer 3A in plan view, implanting donor impurity ions into the P layer in regions corresponding to the N⁺ layers 11a and 11b by, for example, an ion implantation method, and subsequently performing heat treatment. In this case, the N⁺ layers 11a and 11b are formed in the P layer having, in plan view, the same shape as that of the P layer 3A in line B. The same also applies to the N⁺ layers 11aa and 11ba.

A process of forming a memory cell and a MOS transistor of a logic circuit on the same substrate will be described with reference to FIGS. 8AA and 8AB to FIGS. 8LA and 8LB. In the figures, figures suffixed with A are sectional views of a memory cell, and figures suffixed with B are sectional views of a MOS transistor of a logic circuit formed on the same substrate as that of the memory cell.

As illustrated in FIGS. 8AA and 8AB, in a memory cell region in FIG. 8AA, an N layer 22 is formed as an upper layer of a P layer substrate 20. In a logic circuit region illustrated in FIG. 8AB, a P layer substrate 21 connecting to the P layer substrate 20 illustrated in FIG. 8AA and having a surface that is flush with an upper surface of the N layer 22 at a height of line A′ (slightly higher than line A in FIGS. 4AA and 4AB) is disposed. The N layer 22 is formed by, for example, ion implantation into the P layer substrate 20, plasma impurity doping, or an epitaxial crystal growth method. The epitaxial crystal growth method includes steps such as etching the P layer 20 to a predetermined depth, subsequently epitaxially growing crystals of a semiconductor layer containing a donor impurity, and performing surface chemical mechanical polishing (CMP) for making the surface of the memory cell region and the surface of the logic circuit region flush with each other.

Next, as illustrated in FIGS. 8BA and 8BB, P layers 23a and 23b are formed on the N layer 22 and on the P layer 21, respectively, at the same time by, for example, an epitaxial crystal growth method. Subsequently, a mask material layer 24a is formed on the P layer 23a, and a mask material layer 24b is formed on the P layer 23b.

Next, as illustrated in FIGS. 8CA and 8CB, the P layers 23a and 23b are etched by, for example, a reactive ion etching (RIE) method using the mask material layers 24a and 24b as a mask such that an etching bottom portion is positioned at the height of line A to form P layers 25a and 25b having a rectangular shape in plan view and having a pillar shape in a vertical section. In the memory cell region, the etching is performed such that the etching bottom portion is positioned at an upper portion of the N layer 22a. As a result, the surface of the outer peripheral portion of the P layer 25a in the memory cell region and the surface of the outer peripheral portion of the P layer 25b in the logic circuit region are substantially flush with each other at a height of line A. In addition, the surfaces of top portions of the P layer 25a and the P layer 25b are substantially flush with each other at a height of line C. In actual RIE etching, for example, the difference in impurity concentration between the N layer 22a and the P layer 21 and the difference in position where the P layers 25a and 25b stand cause a slight difference in etching rate. This causes a slight difference between the position of the surface of the outer peripheral portion of the P layer 25a in the memory cell region and the position of the surface of the outer peripheral portion of the P layer 25b in the logic circuit region; however, the surfaces are substantially flush with each other at the height of line A. Similarly, the top portion of the P layer 25a and the top portion of the P layer 25b are substantially flush with each other at the height of line C. Note that, when the positions of the bottom portions of the P layers 25a and 25b are made different in the perpendicular direction, the P layers 25a and 25b are separately formed by, for example, covering with an etching mask material layer and using an RIE etching method.

Next, as illustrated in FIGS. 8DA and 8DB, a surface layer of the P layer 25a and a surface layer of the N layer 22 are oxidized to form an insulating layer 27a, and at the same time, a surface layer of the pillar-shaped P layer 25b and a surface layer of the P layer substrate 21 are oxidized to form an oxide insulating layer 27b. The insulating layers 27a and 27b may be formed by another method such as atomic layer deposition (ALD). On the outer peripheral portions and side surfaces of the P layers 25a and 25b, an insulating layer 4 and an insulating layer 4a and a first gate insulating layer 5 and an insulating layer 5a that are separated from each other may be separately formed, as illustrated in FIGS. 4AA and 4AB. Note that the insulating layers 27a and 27b may be separately formed on the side surfaces of the P layers 25a and 25b and on the outer peripheral portions of the bottom portions of the P layers 25a and 25b.

Next, as illustrated in FIGS. 8EA and 8EB, for example, a poly-Si layer 29 containing a donor or acceptor impurity in a large amount is formed so as to surround lower portions of the insulating layers 27a and 27b covering the pillar-shaped P layers 25a and 25b. Subsequently, an insulating layer 30 is formed on the poly-Si layer 29. Thus, in the memory cell region and the logic circuit region, the surfaces of the insulating layers 30 are substantially flush with each other at a height of line B. The insulating layer 30 may be formed by another method, for example, by oxidizing the upper surface of the poly-Si layer 29.

Next, as illustrated in FIGS. 8FA and 8FB, a SiO₂ layer 31 disposed on the insulating layer 30 and having an upper surface that is flush with the upper surfaces of the mask material layers 24a and 24b is formed by a chemical vapor deposition (CVD) method and a CMP method.

Next, as illustrated in FIGS. 8GA and 8GB, material layers 32a and 32b in contact with the mask material layers 24a and 24b and extending in the depth direction of the drawing are formed on the mask material layers 24a and 24b. Subsequently, a SiO₂ layer (not illustrated) is formed by a CVD method to cover the surface and polished by a CMP method such that the upper surface thereof is flush with the upper surfaces of the material layers 32a and 32b to form a SiO₂ layer 33.

Next, as illustrated in FIGS. 8HA and 8HB, after the SiO₂ layers 31 and 33 are removed, the exposed oxide insulating layers 27a and 27b are etched to form oxide insulating layers 27aa and 27ba.

Next, as illustrated in FIGS. 8IA and 8IB, N⁺ layers 35a and 35b containing a donor impurity are respectively formed on the left side surface and the right side surface of the exposed P layer 25a. At the same time, N⁺ layers 35aa and 35ba containing a donor impurity are respectively formed on the left side surface and the right side surface of the exposed P layer 25b using, for example, a selective epitaxial crystal growth method.

Next, the entire structure is covered with a SiO₂ layer (not illustrated). Subsequently, as illustrated in FIGS. 8JA and 8JB, the SiO₂ layer is polished by a CMP method such that the upper surface of the SiO₂ layer is flush with the upper surfaces of the material layers 32a and 32b to form a SiO₂ layer 36a. Subsequently, the material layers 32a and 32b and the mask material layers 24a and 24b are removed to form holes 50a and 50b.

Next, as illustrated in FIGS. 8KA and 8KB, HfO₂ layers 37a and 37b and TiN layers 38a and 38b are formed, from the inside, in the holes 50a and 50b. The HfO₂ layers 37a and 37b may be other material layers composed of a single layer or a plurality of layers as long as the material layers serve as gate insulating layers. Similarly, the TiN layers 38a and 38b may be other material layers composed of a single layer or a plurality of layers as long as the material layers serve as gate conductor layers. The TiN layer 38a may be formed of a metal wiring layer connecting between a gate conductor layer on the P layer 25a and a gate conductor layer of an adjacent memory cell in plan view. This also applies to the other embodiments.

Next, as illustrated in FIGS. 8LA and 8LB, the entire structure is covered with an insulating layer 36b. Subsequently, a wiring conductor layer 39 connecting to the N⁺ layer 35a through a formed contact hole and a wiring conductor layer 41 connecting to the N⁺ layer 35aa through a formed contact hole are formed on the insulating layer 36b. The entire structure is covered with an insulating layer 36c. Subsequently, a wiring conductor layer 40 connecting to the N⁺ layer 35b through a formed contact hole and a wiring conductor layer 42 connecting to the N⁺ layer 35ba through a formed contact hole are formed on the insulating layer 36c. The wiring conductor layer 39 connects to a source line SL. The wiring conductor layer 40 that extends orthogonal to the TiN layer 38a connecting to a word line WL in plan view connects to a bit line BL. The wiring conductor layer 41 connects to a source line S. The TiN layer 38b connects to a gate line G. The wiring conductor layer 42 connects to a drain line D. The poly-Si layer 29a connects to a plate line PL. Thus, a memory cell and an N-channel MOS transistor are formed on the P layer substrates 20 and 21 that are connected together. The MOS transistor of the memory cell and the MOS transistor of the logic circuit that are formed on the insulating layer 30 are formed by the same steps in the perpendicular direction. This simplifies the production method. Furthermore, also in the formation of the poly-Si layer 29 of the memory cell and portions of the insulating layers 27aa, 27ba, and 30, many steps can be shared in the memory cell and the logic circuit, and thus the production method is simplified.

Note that the shapes of the wiring conductor layers 41 and 42 in the logic circuit region in plan view are determined by connections of wiring lines between MOS transistors in the logic circuit design.

In FIGS. 8EA and 8EB to FIGS. 8HA and 8HB, the poly-Si layer 29 serving as a gate conductor layer is formed, the poly-Si layer 29 in the logic circuit region is then removed, and the SiO₂ layer 31 is embedded in the resulting space. Alternatively, first, an insulating layer may be formed instead of the poly-Si layer 29, the insulating layer in the memory cell region may be removed, and an insulating layer surrounding the P layer 25a and corresponding to the oxide insulating layer 27aa and a gate conductor layer may then be formed on the removed portion.

The TiN layers 38a and 38b may be formed by a method such as a gate-first process or a gate-last process (refer to, for example, Martin M. Frank, “High-k/Metal Gate Innovations Enabling Continued CMOS Scaling” Proc. of the 41th European Solid-state Device Research Conference pp. 50-58 (2011)).

In FIGS. 8CA and 8CB, the P layers 23a and 23b are etched by, for example, a reactive ion etching (RIE) method using the mask material layers 24a and 24b as a mask such that an etching bottom portion is positioned at the height of line A to form the P layers 25a and 25b having a rectangular shape in plan view and having a pillar shape in the vertical section. In contrast, the pillar-shaped P layers 25a and 25b in the memory cell region and the logic circuit region may be separately formed, and bottom portions of the pillar-shaped P layers 25a and 25b in the memory cell region and the logic circuit region may be positioned at different heights. In this case, for example, a poly-Si layer 29 containing a donor or acceptor impurity in a large amount is formed so as to surround lower portions of the insulating layers 27a and 27b covering the pillar-shaped P layers 25a and 25b illustrated in FIGS. 8EA and 8EB. An insulating layer 30 is then formed on the poly-Si layer 29. As a result, in the memory cell region and the logic circuit region, the surfaces of the insulating layers 30 are substantially flush with each other at a height of line B as in FIGS. 8EA and 8EB. This also applies to the other embodiments.

The impurity concentrations of the P layer 25a and the P layer 25b may be different in accordance with the design requirements. Similarly, the material layers constituting the HfO₂ layers 37a and 37b and the gate conductor layers 38a and 38b and the thicknesses thereof may be different in accordance with the design requirements. These also apply to the other embodiments.

In FIGS. 8AB to 8LB, a method for producing an N-channel MOS transistor in the logic circuit region has been described. In the actual logic circuit region, a P-channel MOS transistor is also formed. In the P-channel MOS transistor, the N⁺ layers 35aa and 35ba in the N-channel MOS transistor are formed as P⁺ layers containing an acceptor impurity in a large amount, and the materials, the thicknesses, and the like of the gate insulating layer 37b and the gate conductor layer 38b may be changed in some cases in accordance with the design requirements; however, the basic structure of the P-channel MOS transistor is the same as that of the N-channel MOS transistor. For electrical isolation from the N-channel MOS transistor, a well structure may be used.

In the formation of the P layer 25a, a material layer serving as a gate conductor layer or a dummy gate layer, and insulating layers on and under the material layer are deposited so as to have a layer structure, a hole extending through these layers is then formed, and the P layer 25a may be formed by, for example, a selective epitaxial crystal growth method or a metal-induced lateral crystallization (MILC) method (refer to, for example, H. Miyagawa et al., “Metal-Assisted Solid-Phase Crystallization Process for Vertical Monocrystalline Si Channel in 3D Flash Memory”, IEDM19 digest paper, pp. 650-653 (2019)). The first gate conductor layer 29a may be formed by etching a dummy gate material formed at first, and subsequently embedding the first gate conductor layer 29a in the resulting space.

An example of another process of forming a memory cell and a MOS transistor of a logic circuit on the same substrate will be described with reference to FIGS. 9AA and 9AB to FIGS. 9CA and 9CB. In the figures, figures suffixed with A are sectional views of a memory cell, and figures suffixed with B are sectional views of a MOS transistor of a logic circuit formed on the same substrate as that of the memory cell.

As illustrated in FIGS. 9AA and 9AB, the same mask material layer 24a as that in FIG. 8BA is formed in the memory cell region of a P layer substrate 20a, and the same mask material layer 24b as that in FIG. 8BB is formed in the logic circuit region of the P layer substrate 20a.

Next, as illustrated in FIGS. 9BA and 9BB, the P layer substrate 20a is etched by an RIE method using the mask material layers 24a and 24b as an etching mask to form pillar-shaped P layers 25a and 25b. In the logic circuit region, a SiO₂ layer 45 having an upper surface flush with an upper surface of the mask material layer 24b is formed. In the memory cell region, for example, a silicon nitride (SiN) layer 46 is formed so as to cover the P layer 25a and the mask material layer 24a. Subsequently, for example, arsenic (As) ions are implanted by an ion implantation method into an upper portion of the P layer substrate in an outer peripheral portion of the P layer 25a to form an N layer 22a.

Next, as illustrated in FIGS. 9CA and 9CB, an N layer 22A is formed by thermal diffusion of a donor impurity from the N layer 22a due to heat treatment. A SiO₂ layer 47 is formed by thermal oxidation. The SiO₂ layer 47 corresponds to the insulating layer 27a on the outer peripheral portion of the bottom portion of the P layer 25a in FIGS. 8EA and 8EB. After the SiN layer 46 and the SiO₂ layer 45 are removed, the same steps as those illustrated in FIGS. 8DA and 8DB to FIGS. 8LA and 8LB are performed to form a memory cell and a MOS transistor of a logic circuit.

In the steps illustrated in FIGS. 8AA and 8AB to FIGS. 8EA and 8EB, after the N layer 22 is formed, as illustrated in FIGS. 8CA and 8CB, the P layer 23a is etched using the mask material layer 24a as an etching mask such that an etching end point is present near the upper surface of the N layer 22 to form the pillar-shaped P layer 25a. Therefore, the positional relationship between an upper end of the N layer 22 in contact with the bottom portion of the P layer 25a and a bottom portion of the poly-Si layer 29 serving as a gate conductor layer in the perpendicular direction is determined by the accuracy of RIE etching of the Player 20a and uniformity of the entire wafer. In contrast, in FIGS. 9AA and 9AB to FIGS. 9CA and 9CB, the P layer 25a is formed by RIE etching in advance, and the formation of the N layer 22a by ion implantation into the upper surface of the P layer substrate 20 and the formation of the SiO₂ layer 47 by thermal oxidation are then performed. In addition, the insulating layer 27a is formed by an ALD method with high accuracy or thermal oxidation method. Therefore, the positional relationship between a bottom portion of the poly-Si layer 29 and an upper end of the N layer 22A in contact with the bottom portion of the P layer 25a in the perpendicular direction is determined by thermal oxidation conditions for forming the SiO₂ layer 47 and heat treatment conditions for forming the N layer 22A after ion implantation. Thus, since the positional relationship between the bottom portion of the poly-Si layer 29 and the upper end of the N layer 22A in contact with the bottom portion of the P layer 25a in the perpendicular direction does not depend on the accuracy of RIE etching for forming the P layer 25a or the uniformity, a memory cell with high accuracy and high uniformity is formed. Moreover, since the formation of the P layers 23a and 23b by an epitaxial crystal growth method as illustrated in FIGS. 8AA and 8AB and FIGS. 8BA and 8BB is not necessary, a reduction in the production cost can be achieved.

The P layer substrate 1 in FIG. 1 may be formed of a semiconductor or an insulating layer. Alternatively, the P layer substrate 1 may be a well layer. This also applies to the other embodiments.

In FIG. 1, for example, P⁺ type-polysilicon (P⁺ poly) may be used as the first gate conductor layer 6, and N⁺ type-polysilicon (N⁺ poly) may be used as the second gate conductor layer 10. As long as the first gate conductor layer 6 has a work function higher than the work function of the second gate conductor layer 10, the gate conductor layers may be a combination such as P⁺ poly (5.15 eV)/lamination of W and TiN (4.7 eV), P⁺ poly (5.15 eV)/lamination of silicide and N⁺ poly (4.05 eV), or TaN (5.43 eV)/lamination of W and TiN (4.7 eV). In the case of using an N-type semiconductor as the P layer 3a, as long as the first gate conductor layer 6 has a work function lower than the work function of the second gate conductor layer 10, similar advantages can be provided, for example, when N⁺ poly is used as the first gate conductor layer 6 and P⁺ poly is used as the second gate conductor layer 10. The first gate conductor layer 6 and the second gate conductor layer 10 may be made of a semiconductor, a metal, or a compound thereof. This also applies to the other embodiments.

In FIGS. 4AA and 4AB, the vertical sectional shape of the P layers 3a, 3b, 3aa, and 3ba has been described as being a rectangular shape; alternatively, the vertical sectional shape may be a trapezoidal shape. This also applies to the other embodiments. The horizontal section of the P layers 3a, 3b, 3aa, and 3ba may have a square shape or an oblong shape. This also applies to the other embodiments.

In FIG. 1, the N layer 2 is illustrated as connecting to adjacent memory cells; alternatively, the N layer 2 may be present only in a bottom portion of the P layer 3. In this case, the N layer is not connected to the control line CDC. Also in this case, a normal memory operation can be performed. This also applies to the other embodiments.

When the N layer 2 illustrated in FIG. 1 connects to adjacent memory cells and connects to the control line CDC, an N⁺ layer containing a donor impurity in a large amount or a conductor layer may be provided on a part or over the entire surface of the N layer 2 in the outer peripheral portion of the P layer 3 in plan view. This also applies to the other embodiments.

The N⁺ layer 35a connecting to the source line SL in the memory cell illustrated in FIGS. 8LA and 8LB may be shared by cells adjacent to each other. The N⁺ layer 35b connecting to the bit line BL may be shared by cells adjacent to each other. This enables a higher degree of integration of the memory cell region. This also applies to the other embodiments.

In FIG. 1, the first gate conductor layer 6 may be divided into two parts in a horizontal section so as to be driven synchronously or asynchronously. In the case where driving is performed in synchronization with two divided conductor layers, the same operations as those illustrated in FIGS. 2A to 2C and FIGS. 3A to 3C are performed. In the case where two divided conductor layers are driven asynchronously, for example, a group of positive holes which are signal charges are stored mainly in the P layer 3 on a conductor layer side closer to the N⁺ layer 11a connecting to the source line SL, and a fixed voltage is applied to a conductor layer closer to the N⁺ layer 11b connecting to the bit line BL to suppress deterioration of retention characteristics and disturbance characteristics caused by a change in the electric potential of the P layer 3a due to application of a bit-line access pulse voltage. The first gate conductor layer 6 may be divided into two parts in the perpendicular direction so as to be driven synchronously or asynchronously. In the case where driving is performed in synchronization with two divided conductor layers, the same operations as those illustrated in FIGS. 2A to 2C and FIGS. 3A to 3C are performed. In the case where two divided conductor layers are driven asynchronously, for example, a fixed voltage is applied to a conductor layer closer to the N⁺ layer 11b connecting to the bit line BL, and a change in the electric potential of the P layer 3a surrounded by another conductor layer apart from the N⁺ layer 11b due to application of a bit-line access pulse voltage is reduced to suppress deterioration of retention characteristics and disturbance characteristics. This also applies to the other embodiments.

The P layer substrate 1 in FIG. 1 may be a silicon on insulator (SOI) substrate, a substrate having a well structure, or the like. A MOS transistor circuit isolated by an insulating layer may be provided under the N layer 2. This also applies to the other embodiments.

In FIG. 1, the N⁺ layer 11a and the N⁺ layer 11b may be formed as P⁺ layers in which positive holes serve as the majority carriers (semiconductor regions containing an acceptor impurity at a high concentration), and the memory may be operated with electron serving as carriers for writing. In this case, the first gate conductor layer 6 is preferably made of a material having a work function lower than the work function of the second gate conductor layer 10. This also applies to the other embodiments.

In FIG. 1, a substrate having a P-well structure, a silicon on insulator (SOI) substrate, or the like may be used as the P layer substrate 1. This also applies to the other embodiments.

It is to be understood that various embodiments and modifications of the present invention are possible without departing from the broad spirit and scope of the present invention. The embodiments described above are illustrative examples of the present invention and do not limit the scope of the present invention. The embodiments and modifications can be appropriately combined. Furthermore, some of constituent features of the above embodiments may be omitted as required, and such embodiments still fall within the technical idea of the present invention.

Use of the memory-element-including semiconductor device according to the present invention can provide a semiconductor device with high performance at a low cost.

What is claimed is:

1. A memory-element-including semiconductor device comprising:
a memory element; and
a MOS transistor,
wherein the memory element includes
a pillar-shaped first semiconductor layer that stands on a substrate in a direction perpendicular to the substrate,
a first impurity region connecting to a bottom portion of the first semiconductor layer,
a first gate insulating layer in contact with a side surface of the first semiconductor layer,
a first gate conductor layer in contact with a side surface of the first gate insulating layer,
a first insulating layer disposed between the first impurity region and the first gate conductor layer,
a second semiconductor layer continuous with an upper portion of the first semiconductor layer,
a second impurity region and a third impurity region in contact with both ends of the second semiconductor layer in a horizontal direction,
a second gate insulating layer in contact with the second semiconductor layer between the second impurity region and the third impurity region, and
a second gate conductor layer in contact with the second gate insulating layer,
the MOS transistor includes
a pillar-shaped third semiconductor layer that stands on the substrate in the direction perpendicular to the substrate,
a first material layer in contact with a side surface of the third semiconductor layer,
a fourth semiconductor layer continuous with an upper portion of the third semiconductor layer,
a fourth impurity region and a fifth impurity region in contact with both ends of the fourth semiconductor layer in the horizontal direction,
a third gate insulating layer in contact with the fourth semiconductor layer between the fourth impurity region and the fifth impurity region, and
a third gate conductor layer in contact with the third gate insulating layer, and
a top portion of the first semiconductor layer and a top portion of the third semiconductor layer are located at substantially the same position in the perpendicular direction.

2. The memory-element-including semiconductor device according to claim 1,
wherein the first material layer is an insulating layer.

3. The memory-element-including semiconductor device according to claim 1,
wherein the first material layer is formed of, from a bottom, a second insulating layer, a third insulating layer in contact with the side surface of the third semiconductor layer, a first conductor layer in contact with a side surface of the third insulating layer, and a fourth insulating layer covering the first conductor layer and being in contact with the third insulating layer.

4. The memory-element-including semiconductor device according to claim 3,
wherein a fixed voltage or a voltage that changes with time is applied to the first conductor layer.

5. The memory-element-including semiconductor device according to claim 3, comprising:
a sixth impurity region connecting to a bottom portion of the third semiconductor layer.

6. The memory-element-including semiconductor device according to claim 1,
wherein an upper surface of the second semiconductor layer and an upper surface of the fourth semiconductor layer are located at substantially the same position in the perpendicular direction.

7. The memory-element-including semiconductor device according to claim 1,
wherein a bottom portion of the first semiconductor layer and a bottom portion of the third semiconductor layer are located at substantially the same position in the perpendicular direction.

8. The memory-element-including semiconductor device according to claim 1,
wherein a bottom portion of the first semiconductor layer and a bottom portion of the third semiconductor layer are located at different positions in the perpendicular direction.

9. The memory-element-including semiconductor device according to claim 1,
wherein an entirety or part of the first insulating layer has a material layer that is an extension of the first gate insulating layer.

10. The memory-element-including semiconductor device according to claim 1,
wherein, at a boundary portion between the first semiconductor layer and the second semiconductor layer, in a direction from the second impurity region toward the third impurity region, a length of a top portion of the first semiconductor layer is greater than a length of a bottom portion of the second semiconductor layer,
the second impurity region is formed of, from a side in contact with the second semiconductor layer to the outside, a first low-concentration impurity region having a low impurity concentration and a first high-concentration impurity region having a high impurity concentration, and
the third impurity region is formed of, from the side in contact with the second semiconductor layer to the outside, a second low-concentration impurity region having a low impurity concentration and a second high-concentration impurity region having a high impurity concentration.

11. The memory-element-including semiconductor device according to claim 10,
wherein, at a boundary portion between the third semiconductor layer and the fourth semiconductor layer, in a direction from the fourth impurity region toward the fifth impurity region, a length of a top portion of the third semiconductor layer is greater than a length of a bottom portion of the fourth semiconductor layer,
the fourth impurity region is formed of, from a side in contact with the fourth semiconductor layer to the outside, a third low-concentration impurity region having a low impurity concentration and a third high-concentration impurity region having a high impurity concentration, and
the fifth impurity region is formed of, from the side in contact with the fourth semiconductor layer to the outside, a fourth low-concentration impurity region having a low impurity concentration and a fourth high-concentration impurity region having a high impurity concentration.

12. The memory-element-including semiconductor device according to claim 1,
wherein a transistor composed of the second semiconductor layer, the second gate insulating layer, the second gate conductor layer, the second impurity region, and the third impurity region of the memory element is a planar MOS transistor, and a transistor composed of the fourth semiconductor layer, the third gate insulating layer, the third gate conductor layer, the fourth impurity region, and the fifth impurity region is a planar MOS transistor.

13. The memory-element-including semiconductor device according to claim 1,
wherein a transistor composed of the second semiconductor layer, the second gate insulating layer, the second gate conductor layer, the second impurity region, and the third impurity region of the memory element is a planar MOS transistor, and a transistor composed of the fourth semiconductor layer, the third gate insulating layer, the third gate conductor layer, the fourth impurity region, and the fifth impurity region is a fin MOS transistor.

14. The memory-element-including semiconductor device according to claim 1,
wherein a transistor composed of the second semiconductor layer, the second gate insulating layer, the second gate conductor layer, the second impurity region, and the third impurity region of the memory element is a MOS transistor in which the second semiconductor layer has a U-shaped section.

15. The memory-element-including semiconductor device according to claim 1,
wherein the first impurity region connects to a bottom portion of a first semiconductor layer of another memory cell adjacent to the first semiconductor layer.

16. The memory-element-including semiconductor device according to claim 1,
wherein the first impurity region is isolated from an impurity layer in a bottom portion of a first semiconductor layer of another memory cell adjacent to the first semiconductor layer.

17. The memory-element-including semiconductor device according to claim 1,
wherein the first gate conductor layer is divided into two parts in a horizontal section.

18. The memory-element-including semiconductor device according to claim 1,
wherein the first gate conductor layer is divided into two parts in the perpendicular direction.

19. The memory-element-including semiconductor device according to claim 1,
wherein the first insulating layer is a thermally oxidized layer.

20. The memory-element-including semiconductor device according to claim 1,
wherein the first impurity region, the second impurity region, the third impurity region, the first gate conductor layer, and the second gate conductor layer are configured to perform
a memory write operation of controlling voltages applied to the first impurity region, the second impurity region, the third impurity region, the first gate conductor layer, and the second gate conductor layer to generate, in the second semiconductor layer, a group of electrons and a group of positive holes by an impact ionization phenomenon using a current flowing between the second impurity region and the third impurity region or by a gate-induced drain-leakage current and cause, of the generated group of electrons and the generated group of positive holes, a portion or entirety of the group of electrons or the group of positive holes serving as majority carriers to remain mainly in the first semiconductor layer surrounded by the first gate insulating layer, and
a memory erase operation of discharging the group of electrons or the group of positive holes serving as the remaining majority carriers mainly from one or both of the second impurity region and the third impurity region.
